(19) United States
(12) Patent Application Publication
(10) Pub. No.: US 2017/0125364 A1
(43) Pub. Date: May 4, 2017

(54) INTEGRATED CIRCUIT DEVICE HAVING THROUGH VIA BASED ALIGNMENT KEYS AND METHODS OF FORMING THE SAME

(71) Applicant: Samsung Electronics Co., Ltd., Suwon-si (KR)

(72) Inventors: Jung-Hyun Cho, Hwaseong-si (KR); Kwang-Ho Ryu, Seoul (KR); Ji-Hye Shin, Suwon-si (KR); Jin-Ho Chun, Seoul (KR)

(21) Appl. No.: 15/251,575

(22) Filed: Aug. 30, 2016

(30) Foreign Application Priority Data
Oct. 30, 2015 (KR) 10-2015-0152526

(51) Int. Cl. H01L 23/00; H01L 23/528; G11C 8/10; H01L 23/48

(52) U.S. Cl. CPC H01L 24/02; H01L 23/481; H01L 23/528; H01L 24/05; H01L 24/13; G11C 8/10; H01L 2224/0217; H01L 2224/02331; H01L 2224/02372; H01L 2224/02373; H01L 2224/0401; H01L 2224/05024; H01L 2224/13026

(57) ABSTRACT

An integrated circuit device can include a first Through Via (TV) region including first TV structures that are spaced apart from one another at a first pitch in first and second directions. A second TV region can include second TV structures that are spaced apart from one another at the first pitch in the first and second directions. A TV free region can separate directly adjacent first and second TV structures from one another by a spacing distance measured in the first or second direction that is greater than the first pitch and an alignment key can be defined as a geometric pattern including one of the second TV structures and the TV free region.

### CROSS-REFERENCE TO RELATED APPLICATION

This application claims the benefit of Korean Patent Application No. 10-2015-0152526, filed on Oct. 30, 2015, in the Korean Intellectual Property Office, the disclosure of which is incorporated herein in its entirety by reference.

### FIELD

The inventive concept relates to integrated circuit devices, and more particularly, to integrated circuit devices having through silicon via (TSV) structures.

### BACKGROUND

Through silicon via (TSV) technology can provide vertical electrical contacts by penetrating through a substrate or a die.

### SUMMARY

In some embodiments according to the inventive concept, an integrated circuit device can include a first Through Via (TV) region including first TV structures that are spaced apart from one another at a first pitch in first and second directions. A second TV region can include second TV structures that are spaced apart from one another at the first pitch in the first and second directions. A TV free region can separate directly adjacent first and second TV structures from one another by a spacing distance measured in the first or second direction that is greater than the first pitch and an alignment key can be defined as a geometric pattern including one of the second TV structures and the TV free region.

In some embodiments according to the inventive concept, an integrated circuit device can include a through silicon via (TSV) unit region including a first region having a plurality of first TSV structures penetrating through a substrate, where the plurality of first TSV structures can be arranged in the TSV unit region at a constant first pitch in a row direction and in a column direction. A peripheral region can surround the TSV unit region to separate the TSV unit region from adjacent decoder circuits. A second region can be included in at least one region selected from the TSV unit region and the peripheral region, second region can include at least one second TSV structure. A third region can be free of TSV structures, where the third region can be configured to provide a spacing distance between the first region and the second region that is greater than the first pitch. An alignment key can be configured as a combination of at least a portion of the third region and the at least one second TSV structure.

In some embodiments according to the inventive concept, an integrated circuit device can include a plurality of through-silicon via (TSV) unit regions including a plurality of first TSV structures that can penetrate through a substrate and first TSV structures can be regularly arranged with a first pitch. A peripheral region can surround the plurality of TSV unit regions to separate the TSV unit regions from adjacent decoder circuits. At least one second TSV structure can be located across a spacing region, which provides a spacing distance greater than the first pitch, spaced apart from the plurality of first TSV structures, the at least one second TSV structure located in the plurality of TSV unit regions and the peripheral region. An alignment key can include a combination of the at least one second TSV structure and the spacing region.

### BRIEF DESCRIPTION OF THE DRAWINGS

Embodiments of the inventive concept will be more clearly understood from the following detailed description taken in conjunction with the accompanying drawings in which:

FIG. 1 is a plan layout diagram of an integrated circuit device according to embodiments of the inventive concept;

FIG. 2A is a plan view illustrating a through silicon via (TSV) region of an integrated circuit device according to an embodiment of the inventive concept, and FIG. 2B is a cross-sectional view taken along line B-B′ of FIG. 2A;

FIGS. 3A to 3H are plan views of TSV regions of integrated circuit devices according to embodiments of the inventive concept;

FIGS. 4A to 4C are plan views of TSV regions of integrated circuit devices according to embodiments of the inventive concept;

FIG. 5 is a flowchart illustrating a method of manufacturing an integrated circuit device according to embodiments of the inventive concept;

FIGS. 6A to 6K are cross-sectional views illustrating a method of manufacturing an integrated circuit device according to embodiments of the inventive concept; and

FIG. 7 is a block diagram illustrating an electronic device according to embodiments of the inventive concept.

### DETAILED DESCRIPTION OF EMBODIMENTS

Embodiments of the inventive concept will be described in detail with reference to the accompanying drawings. Like reference numerals denote like elements in the drawings.

Embodiments may, however, be embodied in many different forms and should not be construed as being limited to the embodiments set forth herein; rather, these embodiments are provided so that this disclosure will be thorough and complete, and will fully convey the concept of embodiments to those skilled in the art.

While such terms as “first,” “second,” etc., may be used to describe various elements, regions, layers, portions, and/or components in the specification, such elements, regions, layers, portions, and/or components should not be limited to the above terms. The above terms do not refer to a specific order, superiority, or priority, and are used only to distinguish one member, region, portion, or component from another. Accordingly, a first element, region, portion or component which will be described hereinafter could be termed a second element, region, portion, or component without departing from the description of the inventive concept. For example, the first element could be termed the second element, without departing from the scope of the inventive concept, and similarly, the second element could be termed the first element.

Unless defined differently, terms used in the specification include meanings of technical and scientific terms, and have the same meaning as generally understood by one of ordinary skill in the art to which the inventive concept belongs. Further, it should be understood that the terms, such as those defined in commonly used dictionaries, should be interpreted as having a meaning that is consistent with their meaning in the context of the relevant art. Here, unless clearly defined, it should be understood that the terms should not be interpreted as having overly formal meaning.

When any embodiment is able to be implemented differently, a specific process sequence may be performed differently from the sequence which will be described. For example, two processes which are sequentially described may be substantially performed simultaneously, and reversely.

For example, in the accompanying drawings, changes of shown shapes may be predicted due to manufacturing technology and/or tolerance. Accordingly, embodiments of the inventive concept should not be construed as being limited to a specific shape of a region shown in the specification, and for example, should include changes of the shape occurring in a manufacturing process. The term “and/or” used herein may include elements described, alone or in combination. Further, the term “substrate” used herein may refer to the substrate itself, or a stacked structure including a predetermined layer or film, etc. formed on the substrate or its surface. Moreover, the “surface of the substrate” used in this specification may refer to an exposure surface of the substrate itself, or an outer surface of the predetermined layer or film, etc. formed on the substrate.

In some embodiments, an integrated may include an alignment key including a combination of at least one TSV structure and a region which does not include the TSV structure which is a region adjacent to the at least one TSV structure. The at least one TSV structure used in the alignment key may be an active TSV structure which electrically connects unit devices formed on a substrate and conductive components arranged on a back side of the substrate, and performs an electrical function in the integrated circuit device. As appreciated by the present inventors, since function components are used as the alignment key, it may not be necessary to perform a separate process for forming an alignment key in another region of the substrate for forming the integrated circuit device, for example, the scribe lane region, etc. Accordingly, the manufacturing process of an integrated circuit device including a TSV device may be simplified and the productivity may be improved.

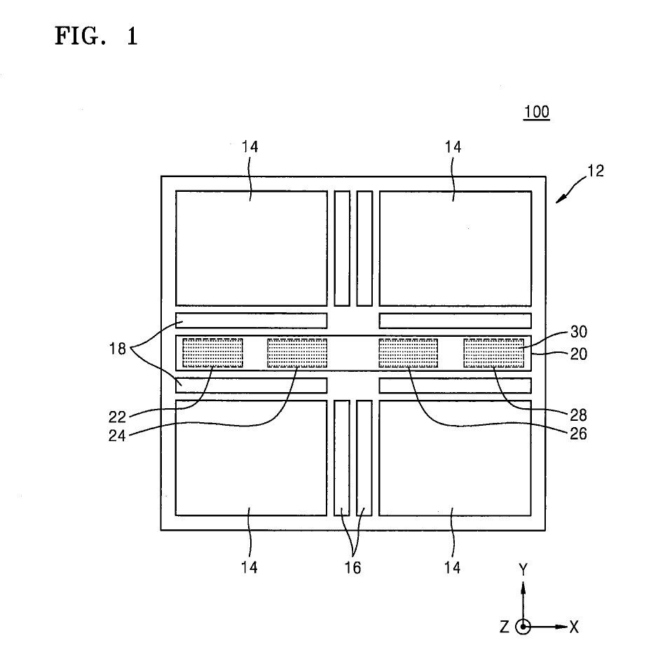

FIG. 1 is a plan layout of an integrated circuit device according to embodiments of the inventive concept.

Referring to FIG. 1, an integrated circuit device 100 may include a memory chip 12 including a plurality of memory blocks 14. A plurality of memory cells may be arranged in the plurality of memory blocks 14. A plurality of word lines, a plurality of bit lines, sense amplifiers, etc. may be arranged in the plurality of memory blocks 14 in various manners. A plurality of column decoders 16, a plurality of row decoders 18, and a through silicon via (TSV) region 20 may be arranged around (or between) the plurality of memory blocks 14. The plurality of column decoders 16 may receive an address, and select a column line of the memory block 14 by decoding the address. The plurality of row decoders 18 may receive an address, and output a row address for selecting a row line of the memory block 14 by decoding the address. The memory chip 12 may further include a write driver, an input and output sense amplifier, and an input and output buffer.

The TSV region 20 may be approximately located in a center portion (in one dimension) of the memory chip 12. A plurality of TSV structures 30 may be arranged in the TSV region 20. The number of the plurality of TSV structures 30 and their shape shown in FIG. 1 is only an example, and the scope of the inventive concept is not limited thereto. For example, approximately hundreds or thousands of TSV structures 30 may be arranged in the TSV region 20.

An input and output buffer included in the memory chip 12 may receive a signal through the TSV structure 30, or transmit a signal through the TSV structure 30. It will be understood that the term “TSV” can include materials other than silicon.

The TSV region 20 may include a plurality of TSV unit regions 22, 24, 26, and 28. The plurality of TSV unit regions 22, 24, 26, and 28 may include a first TSV unit region 22, a second TSV unit region 24, a third TSV unit region 26, and a fourth TSV unit region 28. An example in which the TSV region 20 includes four TSV unit regions 22, 24, 26, and 28 as illustrated in FIG. 1, but the scope of the inventive concept is not limited thereto. The number of the TSV unit regions included in the TSV region 20 may vary.

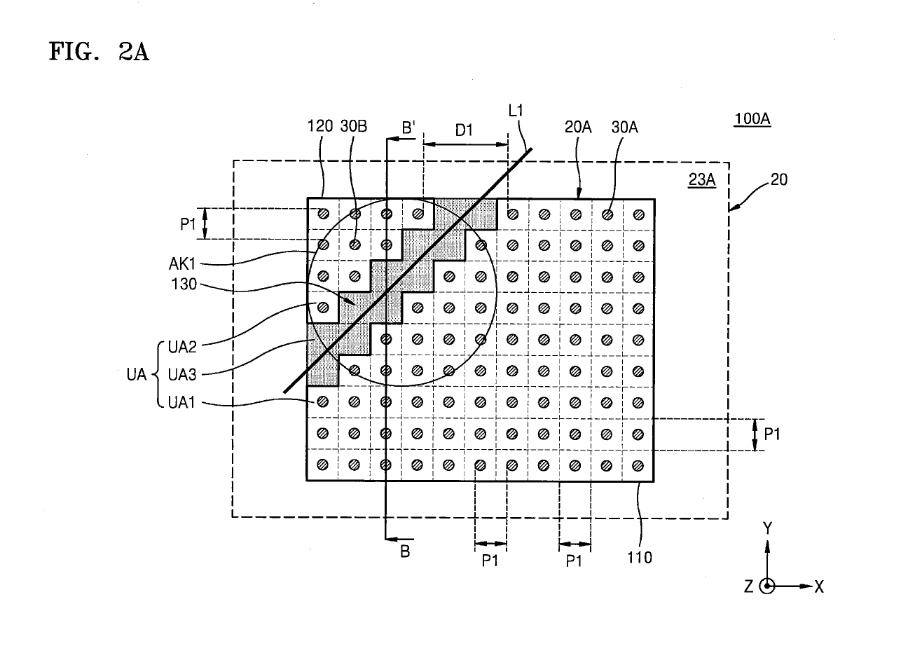

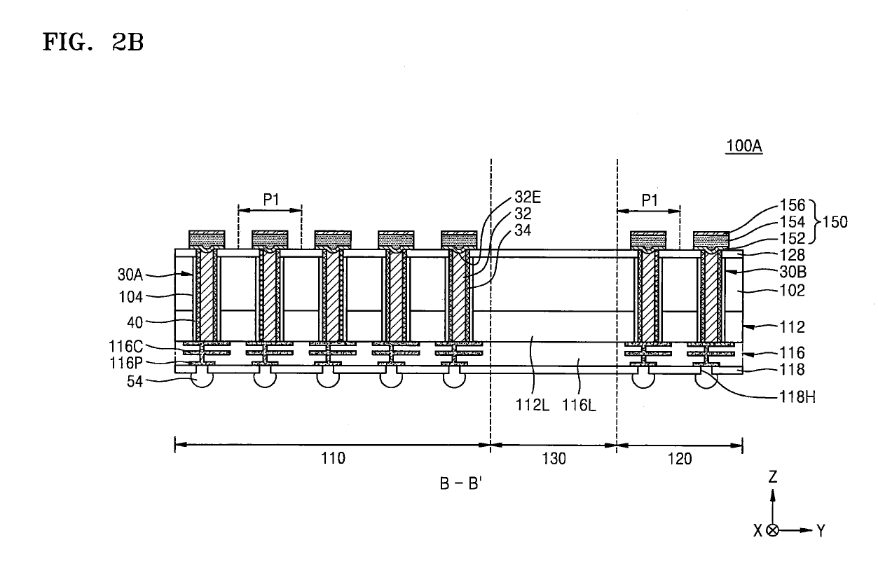

FIGS. 2A and 2B illustrate an integrated circuit device 100A according to embodiments of the inventive concept, and FIG. 2A is an enlarged plan view illustrating a TSV unit region 20A, which may be one of the plurality of TSV unit regions 22, 24, 26, and 28 included in the TSV region 20 in the integrated circuit device 100 shown in FIG. 1, and its peripheral region 23A. FIG. 2B is a cross-sectional view taken along line B-B′ of FIG. 2A.

The TSV unit region 20A shown in FIGS. 2A and 2B may be at least one of the plurality of unit regions 22, 24, 26, and 28 shown in FIG. 1.

Referring to FIGS. 2A and 2B, the integrated circuit device 100A may have a semiconductor structure including a substrate 102, a front-end-of-line (FEOL) structure 112, and a back-end-of-line (BEOL) structure 116.

The TSV region 20 of the integrated circuit device 100A may include the substrate 102, and a plurality of TSV structures 30A and 30B penetrating through the FEOL structure 112. The plurality of TSV structures 30A and 30B may include a plurality of first TSV structures 30A and a plurality of second TSV structures 30B.

The TSV region 20 may include the TSV unit region 20A, and the peripheral region 23A surrounding the TSV unit region 20A.

The TSV region 20 may include a first region 110 in which the plurality of first TSV structures 30A are arranged with a constant first pitch P1 along a row direction (an X direction) and a column direction (a Y direction) in the TSV unit region 20A. Further, the TSV unit region 20A, may include a second region 120 including the plurality of second TSV structures 30B. The plurality of second TSV structures 30B formed in the second region 120 may be arranged with the first pitch P1 like the plurality of first TSV structures 30A formed in the first region 110.

The TSV region 20 may further include a third region 130 interposed between the first region 110 and the second region 120. The third region 130 may provide a spacing distance D1 between the first region 110 and the second region 120 that is greater than the first pitch P1. The distance P1 can be the minimum distance between directly adjacent ones of the first TSV structure 30A and the second TSV structure 30B. The third region 130 may not include a TSV structure. Analogous spacing can be provided in other embodiments described herein.

The integrated circuit device 100A may include an alignment key AK1 configured as a combination of at least a portion of the third region 130 and at least one of the plurality of second TSV structures 30B. The alignment key AK1 may be defined as a circular region having a diameter of about 10 to about 250 μm, but the scope of the inventive concept is not limited thereto. In some other embodiments, the alignment key AK1 may have a rectangular region, or an ovular region. Other shapes may also be used.

The TSV unit region 20A may include a plurality of unit regions UA arranged in a matrix formed with the constant first pitch P1 along the row direction (the X direction) and the column direction (the Y direction).

The plurality of first TSV structures 30A may be formed in a plurality of first unit regions UA1 configuring the first region 110 of the plurality of unit regions UA. One first TSV structure 30A may be formed in one first unit region UA1 in the first region 110, and the plurality of first TSV structures 30A may be arranged to correspond to the plurality of first unit regions UA1 one to one.

The plurality of second TSV structures 30B may be formed in a plurality of second unit regions UA2 configuring the second region 120 of the plurality of unit regions UA. In the second region 120, one second TSV structure 30B may be formed in one second unit region UA2, and the plurality of second TSV structures 30B may be arranged to correspond to the plurality of second unit regions UA2 one to one.

The TSV structure may not be formed in a plurality of third unit regions UA3 configuring the third region 130 of the plurality of unit regions UA.

The third region 130 may be provided by the plurality of third unit regions UA3. The plurality of third unit regions UA3 may be arranged so that the third region 130 extend along an oblique direction shown as “L1” in FIG. 2A is provided. The first region 110 and the second region 120 may be spaced apart from each other by arranging the plurality of third unit regions UA3 providing the third region 130 therebetween.

In FIG. 2A, an example in which the plurality of third unit regions UA3 are arranged to extend along an oblique direction L1 is illustrated, but the technical scope of the inventive concept is not limited to that shown in FIG. 2A. For example, the plurality of third unit regions UA3 may be arranged to provide the third region 130 extended between the first region 110 and the second region 120 along at least one of the row direction (the X direction), the column direction (the Y direction), or an arbitrary oblique direction intersecting directions.

The plurality of first TSV structures 30A and the plurality of second TSV structures 30B may be formed using any one of a via-first process, a via-middle process, and a via-last process. Here, the via-first process may be a process of forming a TSV structure penetrating through the substrate 102 before forming the FEOL structure 112 and the BEOL structure 116 on the substrate 102. The via-middle process may be a process of forming a TSV structure penetrating through the substrate 102 and the FEOL structure 112 after forming the FEOL structure 112 and before forming the BEOL structure 116 on the substrate 102. The via-last process may be a process of forming a TSV structure penetrating through the substrate 102, the FEOL structure 112, and the BEOL structure 116 after forming the FEOL structure 112 and the BEOL structure 116 on the substrate 102.

In FIG. 2B, a resultant product in which the plurality of first TSV structures 30A and the plurality of second TSV structures 30B are formed according to the via-middle process is illustrated. That is, the plurality of first TSV structures 30A and the plurality of second TSV structures 30B may be formed to penetrate through the substrate 102 and the FEOL structure 112. However, the scope of the inventive concept is not limited to that shown in FIG. 2B. An integrated circuit device according to the scope of the inventive concept may include a plurality of TSV structures formed by the via-first process or the via-last process.

Referring to FIG. 2B, the plurality of first TSV structures 30A and the plurality of second TSV structures 30B may be formed in a plurality of via holes 104 penetrating through the substrate 102 and the FEOL structure 112. A via insulating film 40 surrounding the plurality of first TSV structures 30A and the plurality of second TSV structures 30B may be formed in the plurality of via holes 104.

The plurality of first TSV structures 30A and the plurality of second TSV structures 30B may include a conductive plug 32 penetrating through the substrate 102 and the FEOL structure 112, and a conductive barrier film 34 surrounding the conductive plug 32.

The substrate 102 may be formed of a semiconductor. In some embodiments, the substrate 102 may include a semiconductor element such as silicon (Si) and germanium (Ge), or a compound semiconductor such as silicon carbide (SiC), gallium arsenide (GaAs), indium arsenide (InAs), and indium phosphide (InP). In some embodiments, the substrate 102 may have a silicon on insulator (SOI) structure. The substrate 102 may include a conductive region, for example, a well in which impurities are doped, or a structure in which impurities are doped. The substrate 102 may have various isolation structures such as a shallow trench isolation (STI) structure. A back side of the substrate 102 may be covered by a backside passivation layer 128. The backside passivation layer 128 may be formed of a silicon oxide, a silicon nitride, a polymer, or a combination thereof.

The FEOL structure 112 may include various kinds of a plurality of individual devices and an interlayer insulating film 112L. The plurality of individual devices included in the FEOL structure 112 may include various microelectronic devices, for example, a metal oxide semiconductor field effect transistor (MOSFET), a system large scale integration (LSI), an image sensor such as a complementary metal oxide semiconductor (CMOS) image sensor (CIS), a micro-electromechanical system (MEMS), a passive device, an active device, etc. The plurality of individual devices may be electrically connected to a conductive region of the substrate 102. Further, each of the plurality of individual devices may be electrically isolated from other individual devices adjacent to itself by the interlayer insulating layer 112L.

The BEOL structure 116 may include a multilayer interconnection structure 116C configured as a plurality of metal wiring layers and a plurality of contact plugs. A portion of the multilayer interconnection structure 116C may be connected to the plurality of first TSV structures 30A and the plurality of second TSV structures 30B.

In some embodiments, the BEOL structure 116 may further include other multilayer interconnection structures including a plurality of metal interconnection layers and a plurality of contact plugs in another region on the substrate 102. The BEOL structure 116 may be formed to include a plurality of interconnection structures for connecting the individual devices included in the FEOL structure 112 and other interconnections. The multilayer interconnection structure 116C and other interconnection structures included in the BEOL structure 116 may be insulated from each other by a metal interlayer insulating film 116L.

One end of each of the plurality of first TSV structures 30A and the plurality of second TSV structures 30B may be connected to a metal interconnection layer of the multilayer interconnection structure 116C included in the BEOL structure 116.

A front side passivation layer 118 may be formed on the metal interlayer insulating film 116L. The front side passivation layer 118 may be formed as a silicon oxide, a silicon nitride, a polymer, or a combination thereof. A hole 118H exposing a bonding pad 116P connected to the multilayer interconnection structure 116C may be formed in the front side passivation layer 118. The bonding pad 116P may be connected to a first connection terminal 54 through the hole 118H.

The other end of each of the plurality of first TSV structures 30A and the plurality of second TSV structures 30B may be connected to a second connection terminal 150. The second connection terminal 150 may have a structure in which an under bump metallurgy (UBM) layer 152, a first metal pad layer 154, and a second metal pad layer 156 are sequentially stacked. However, the structure of the second connection terminal 150 shown in FIG. 2B is only an example, and the second connection terminal 150 may have various structures within the scope of the inventive concept.

In some embodiments, the other end facing the second connection terminal 150 of the conductive plugs 32 configuring the plurality of first TSV structures 30A and the plurality of second TSV structures 30B may have an end surface 32E in which its center portion is recessed toward the substrate 102 to have a lower level than its edge portion. The UBM layer 152 of the second connection terminal 150 may conformally cover the recessed end surface 32E on the recessed end portion 32E to have a shape corresponding to that of the recessed end surface 32E. It will be understood that “conformally” includes shapes where an upper and lower surface of the conformer layer both follow the profile of the layer on which the conformal layer is formed.

Shapes of the first connection terminal 54 and the second connection terminal 150 are not limited to those shown in FIG. 2B, and each may have a shape of a solder ball, a solder bump, or a contact pad. In some embodiments, the first connection terminal 54 may be omitted.

Each of the plurality of first TSV structures 30A and the plurality of second TSV structures 30B may have an active TSV structure for electrically connecting unit devices on the substrate 102 and conductive components arranged on the back side of the substrate 102, and the plurality of first TSV structures 30A and the plurality of second TSV structures 30B may perform an electrical function in the integrated circuit device 100A.

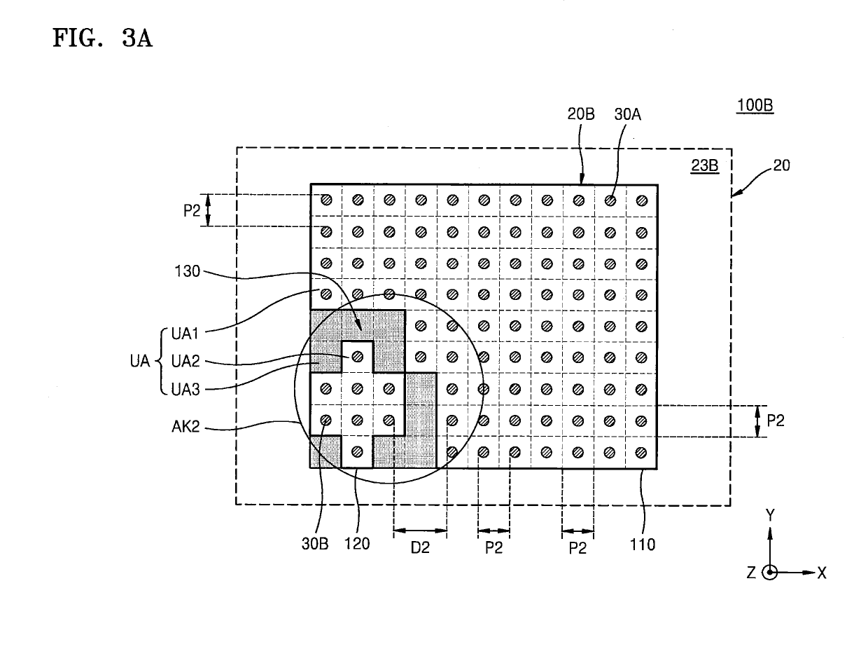

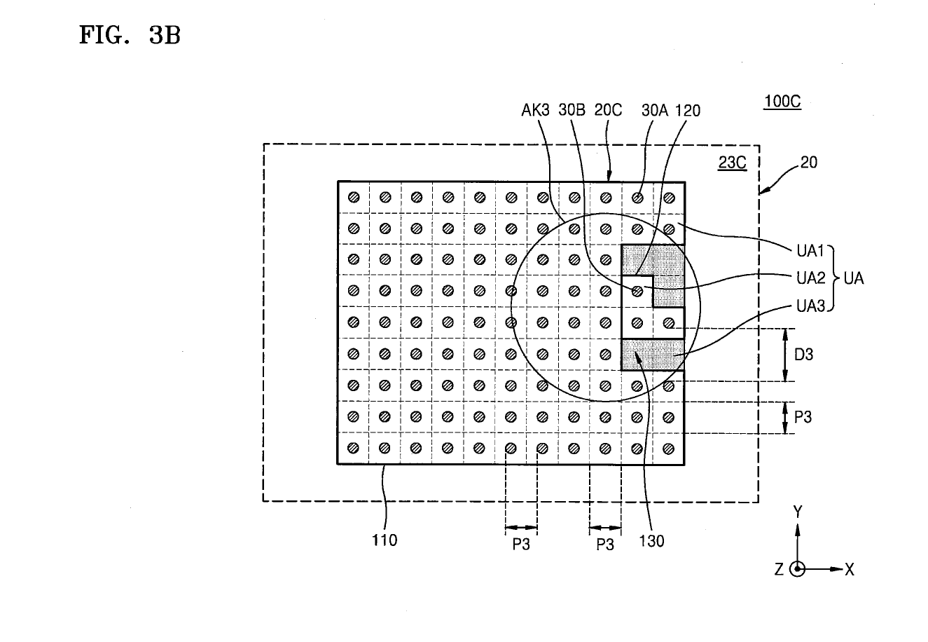

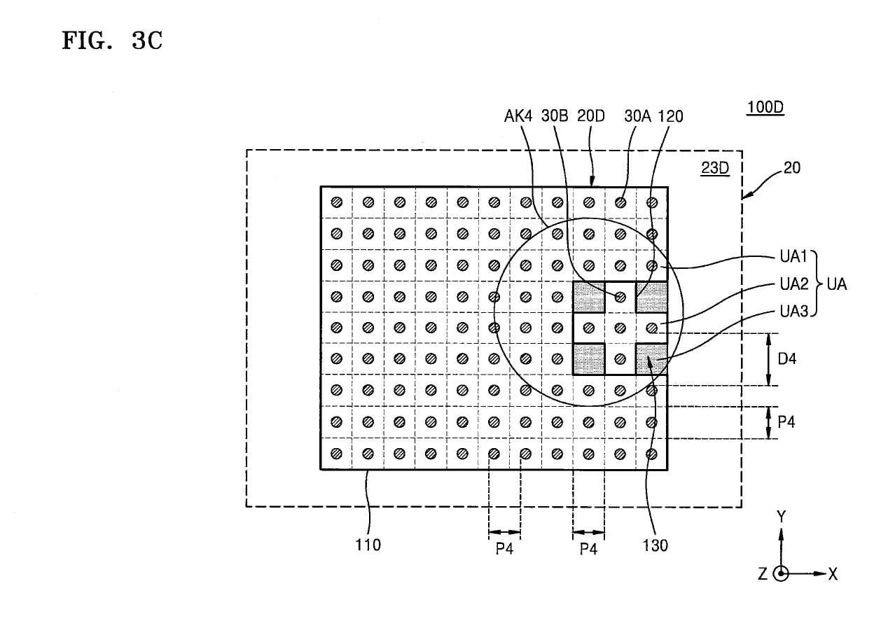

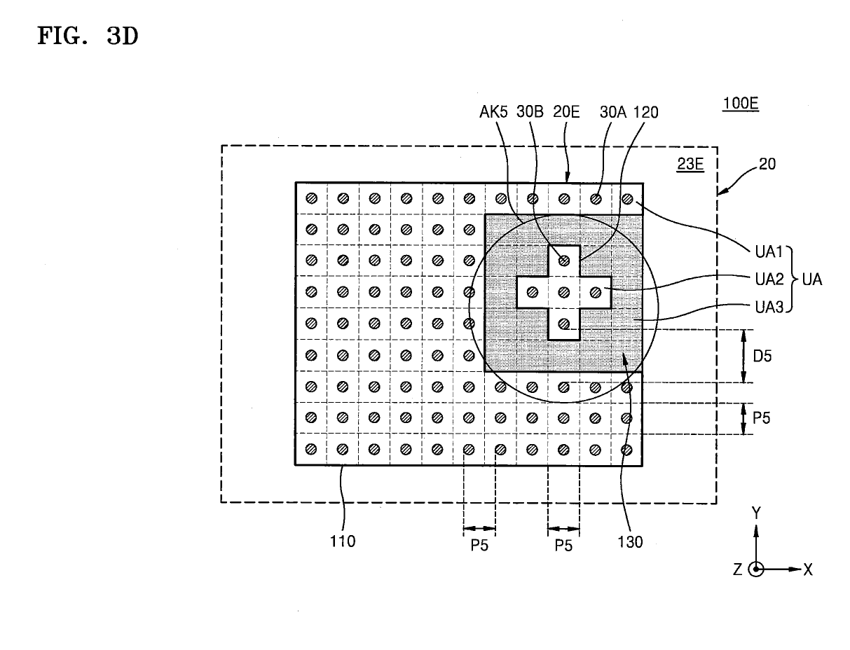

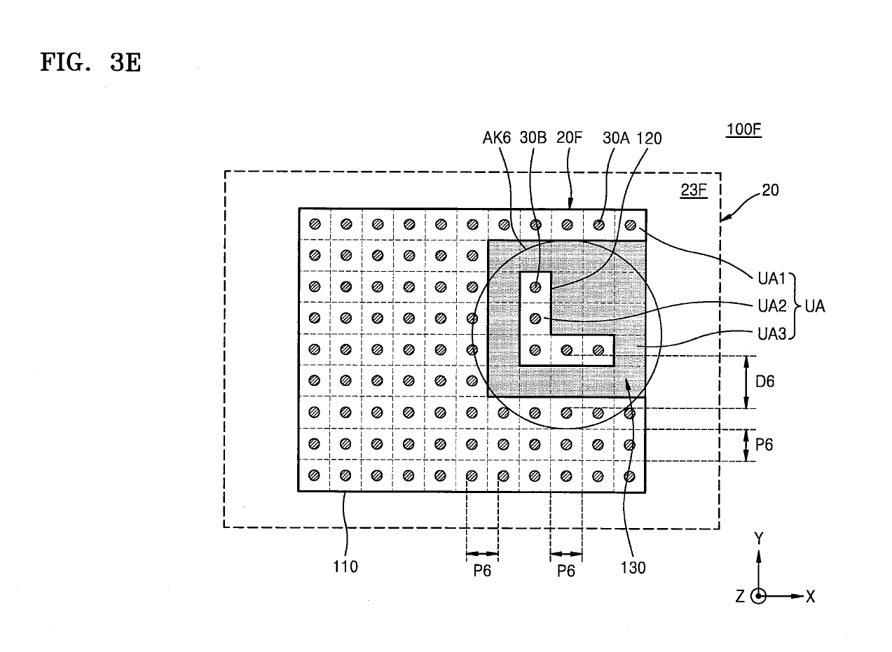

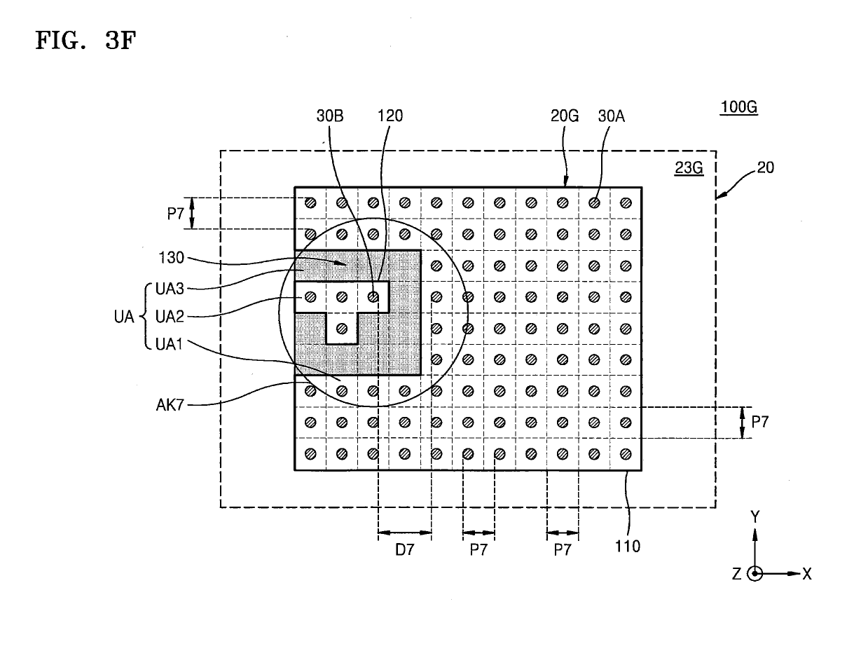

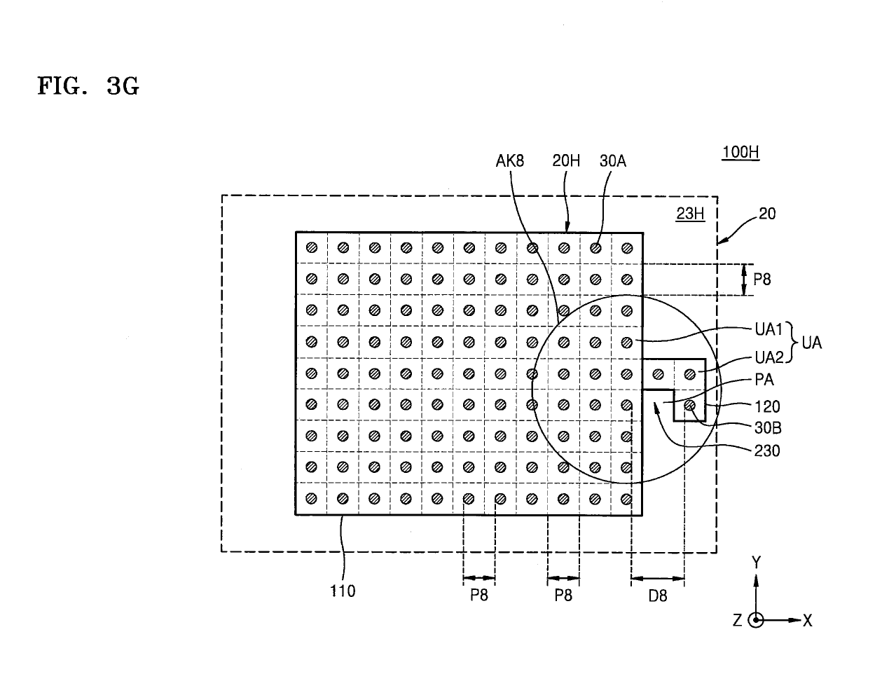

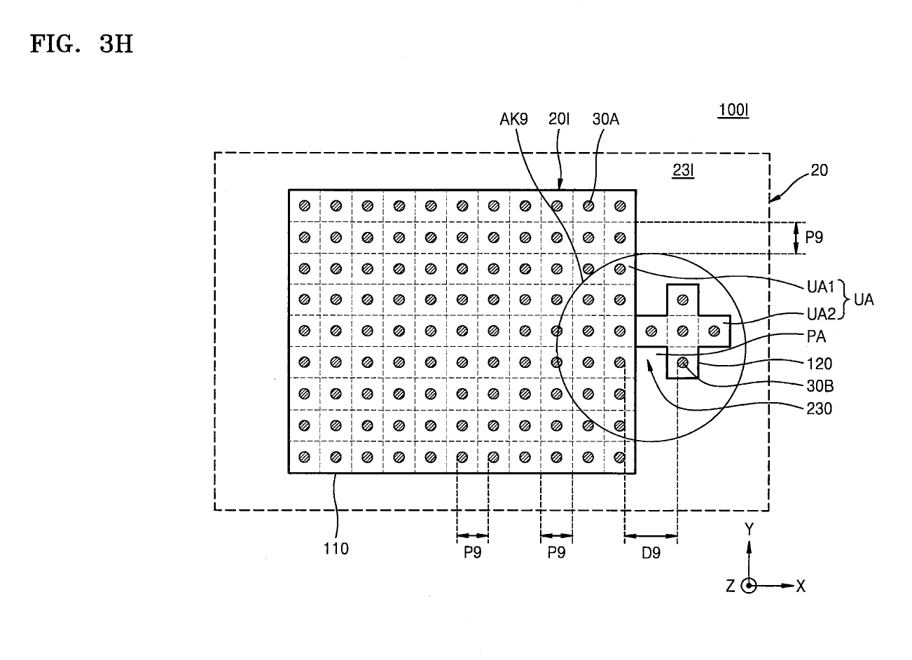

FIGS. 3A to 3H are diagrams of integrated circuit devices 100B, 100C, 100D, 100E, 100F, 100G, 100H, and 100I according to embodiments of the inventive concept, and are enlarged plan views illustrating TSV unit regions 20B, 20C, 20D, 20E, 20F, 20G, 20H, and 20I, which are applicable as at least one of TSV unit regions 22, 24, 26, and 28 included in the TSV region 20 of the integrated circuit device 100 shown FIG. 1, and their peripheral regions 23B, 23C, 23D, 23E, 23F, 23G, 23H, and 23I.

Referring to FIG. 3A, a TSV region 20 of the integrated circuit device 100B may include the TSV unit region 20B and the peripheral region 23B surrounding the TSV unit region 20B.

A plurality of first TSV structures 30A may be arranged with a second pitch P2 in a first region 110 of the TSV unit region 20B, and a plurality of second TSV structures 30B may be arranged with the second pitch P2 in a second region 120 of the TSV unit region 20B like the plurality of the first TSV structures 30A. A third region 130 in which a TSV structure is not formed may be arranged between the first region 110 and the second region 120. At least a portion in the third region 130 may provide a spacing distance D2 that is greater than the second pitch P2 between the first TSV structure 30A and the second TSV structure 30B. The third region 130 may not be interposed between the first region 110 and the second region 120 in a portion of the TSV unit region 20B. In this case, a portion of the second region 120 may border a portion of the first region 110.

In FIG. 3A, an example in which the third region 130 is arranged in only the TSV unit region 20B and is not included outside of the TSV unit region 20B, that is, the peripheral region 23B is illustrated, but the scope of the inventive concept is not limited to the example shown in FIG. 3A. For example, the third region 130 may be arranged to be extended through the TSV unit region 20B and the peripheral region 23B. Further, in FIG. 3A, the spacing distance D2 between one of the first TSV structures 30A and one of the second TSV structures 30B which are located on opposite sides of the third region 130 may be different according to a position. For example, the spacing distance D2 may be less than the second pitch P2 in some portions in the TSV unit region 20B.

The integrated circuit device 100B may include an alignment key AK2 configured as a combination of at least a portion of the third region 130 and at least one of the plurality of second TSV structures 30B. The alignment key AK2 may be configured to have a circular region having a diameter of about 10 to about 250 μm, but the scope of the inventive concept is not limited thereto.

Referring to FIG. 3B, a TSV region 20 of the integrated circuit device 100C may include the TSV unit region 20C and the peripheral region 23C surrounding the TSV unit region 20C.

A plurality of first TSV structures 30A may be arranged with a third pitch P3 in a first region 110 of the TSV unit region 20C, and a plurality of second TSV structures 30B may be arranged with the third pitch P3 like the plurality of first TSV structures 30A in a second region 120. A third region 130 providing a spacing distance D3 greater than the third pitch P3 between the first TSV structure 30A and the second TSV structure 30B may be interposed between the first region 110 and the second region 120. The third region 130 may not include a TSV structure.

The third region 130 may not be interposed between the first region 110 and the second region 120 in a portion of the TSV unit region 20C. In this case, a portion of the second region 120 may border a portion of the first region 110.

In FIG. 3B, the spacing distance D3 between one first TSV structure 30A and one first TSV structure 30B which are located on opposite sides of the third region 130 may be different according to a position.

The integrated circuit device 100C may include an alignment key AK3 configured as a combination of at least a portion of the third region 130 and at least one of the plurality of second TSV structures 30B of the third region 130. The alignment key AK3 may include a circular region having a diameter of about 10 to about 250 μm, but the scope of the inventive concept is not limited thereto.

Referring to FIG. 3C, a TSV region 20 of the integrated circuit device 100D may include the TSV unit region 20D and the peripheral region 23D surrounding the TSV unit region 20D.

A plurality of first TSV structures 30A may be arranged with a fourth pitch P4 in a first region 110 of the TSV unit region 20D, and a plurality of second TSV structures 30B may be arranged with the fourth pitch P4 in a second region 120 like the plurality of first TSV structures 30A. A third region 130 providing a spacing distance D4 greater than the fourth pitch P4 between the first TSV structure 30A and the second TSV structure 30B may be interposed between the first region 110 and the second region 120. The third region 130 may not include a TSV structure.

The third region 130 may not be interposed between the first region 110 and the second region 120 in a portion of the TSV unit region 20D. In this case, a portion of the second region 120 may border a portion of the first region 110.

In FIG. 3C, the spacing distance D4 between one first TSV structure 30A and one second TSV structure 30B which are located on opposite sides of the third region 130 may be different according to a position.

The integrated circuit device 100D may include an alignment key AK4 configured as a combination of at least a portion of the third region 130 and at least one of the plurality of second TSV structures 30B of the second region 120. The alignment key AK4 may include a circular region having a diameter of about 10 to about 250 μm, but the scope of the inventive concept is not limited thereto.

Referring to FIG. 3D, a TSV region 20 of the integrated circuit device 100E may include the TSV unit region 20E and the peripheral region 23E surrounding the TSV unit region 20E.

A plurality of first TSV structures 30A may be arranged with a fifth pitch P5 in a first region 110 of the TSV unit region 20E, and a plurality of second TSV structures 30B may be arranged with the fifth pitch P5 in a second region 120 like the plurality of first TSV structures 30A. A third region 130 providing a spacing distance D5 greater than the fifth pitch P5 between the first TSV structure 30A and the second TSV structure 30B may be interposed between the first region 110 and the second region 120. The third region 130 may not include a TSV structure.

In FIG. 3D, the spacing distance D5 between one first TSV structure 30A and one second TSV structure 30B which are located on opposite sides of the third region 130 may be different according to a position.

The integrated circuit device 100E may include an alignment key AK5 configured as a combination of at least a portion of the third region 130 and at least one of the plurality of second TSV structures 30B of the second region 120. The alignment key AK5 may include a circular region having a diameter of about 10 to about 250 μm, but the scope of the inventive concept is not limited thereto.

Referring to FIG. 3E, a TSV region 20 of the integrated circuit device 100F may include the TSV unit region 20F and the peripheral region 23F surrounding the TSV unit region 20F.

A plurality of first TSV structures 30A may be arranged with a sixth pitch P6 in a first region 110 of the TSV unit region 20F, and a plurality of second TSV structures 30B may be arranged with the sixth pitch P6 in a second region 120 like the plurality of first TSV structures 30A. A third region 130 providing a spacing distance D6 greater than the sixth pitch P6 between the first TSV structure 30A and the second TSV structure 30B may be interposed between the first region 110 and the second region 120. The third region 130 may not include a TSV structure.

In FIG. 3E, the spacing distance D6 between one first TSV structure 30A and one second TSV structure 30B which are located on opposite sides of the third region 130 may be different according to a position.

The integrated circuit device 100F may include an alignment key AK6 configured as a combination of at least a portion of the third region 130 and at least one of the second TSV structures 30B of the second region 120. The alignment key AK6 may include a circular region having a diameter of about 10 to about 250 μm, but the scope of the inventive concept is not limited thereto.

Referring to FIG. 3F, a TSV region 20 of the integrated circuit device 100G may include the TSV unit region 20G and the peripheral region 23G surrounding the TSV unit region 20G.

A plurality of first TSV structures 30A may be arranged with a seventh pitch P7 in a first region 110 of the TSV unit region 20G, and a plurality of second TSV structures 30B may be arranged with the seventh pitch P7 in a second region 120 like the plurality of first TSV structures 30A. A third region 130 providing a spacing distance D7 greater than the seventh pitch P7 between the first TSV structure 30A and the second TSV structure 30B may be interposed between the first region 110 and the second region 120. The third region 130 may not include a TSV structure.

In FIG. 3F, the spacing distance D7 between one first TSV structure 30A and one second TSV structure 30B which are located on opposite sides of the third region 130 may be different according to a position.

The integrated circuit device 100G may include an alignment key AK7 configured as a combination of at least a portion of the third region 130 and at least one of the plurality of second TSV structures 30B of the second region 120. The alignment key AK7 may include a circular region having a diameter of about 10 to about 250 μm, but the scope of the inventive concept is not limited thereto.

Referring to FIG. 3G, a TSV region 20 of the integrated circuit device 100H may include the TSV unit region 20H and the peripheral region 23H surrounding the TSV unit region 20H.

A plurality of first TSV structures 30A may be arranged with a eighth pitch P8 in a first region 110 of the TSV unit region 20H, and a plurality of second TSV structures 30B may be arranged with the eighth pitch P8 in the peripheral region 23H like the plurality of first TSV structures 30A. A third region 230 providing a spacing distance D8 greater than the eighth pitch P8 between the first TSV structure 30A and the second TSV structure 30B may be interposed in a portion between the first region 110 and the second region 120. In the integrated circuit device 100H shown in FIG. 3G, the third region 230 may be included in the peripheral region 23H. A TSV structure may not be formed in a region excluding the second region 120 from the peripheral region 23H. The first region 110 may border a portion of the second region 120.

In FIG. 3G, an example in which the third region 230 is formed in the peripheral region 23H is illustrated, but the scope of the inventive concept is not limited thereto. For example, the third region 230 may be included in only the TSV unit region 20H, and may be included in only the peripheral region 23H, and may be extended from the TSV unit region 20H to the peripheral region 23H so as to be included in both the TSV unit region 20H and the peripheral region 23H.

The integrated circuit device 100H may include an alignment key AK8 configured as a: combination of a portion PA between the first TSV structure 30A and the second TSV structure 30B in the third region 230, and at least one of the plurality of second TSV structures 30B. The alignment key AK8 may include a circular region having a diameter of about 10 to about 250 μm, but the scope of the inventive concept is not limited thereto.

At least one of the plurality of second TSV structures 30B configuring the alignment key AK8 may be arranged in line with the eighth pitch P8 together with a portion of the plurality of first TSV structures 30A.

Referring to FIG. 3H, a TSV region 20 of the integrated circuit device 100I may include the TSV unit region 20I and the peripheral region 23I surrounding the TSV unit region 20I.

A plurality of first TSV structures 30A may be arranged with a ninth pitch P9 in a first region 110 of the TSV unit region 20I, and a plurality of second TSV structures 30B may be arranged with the ninth pitch P9 in the peripheral region 23I like the plurality of first TSV structures 30A. A third region 230 providing a spacing distance D9 greater than the ninth pitch P9 between the first TSV structure 30A and the second TSV structure 30B may be interposed between the first region 110 and the second region 120. The first region 110 may border a portion of the second region 120.

In FIG. 3H, the third region 230 may be included in the peripheral region 23I. A TSV structure may not be formed in a region excluding the second region 120 from the peripheral region 23I.

The integrated circuit device 100I may include an alignment key AK9 configured as a combination of at least a portion PA between the first TSV structure 30A and the second TSV structure 30B in the third region 230, and at least one of the plurality of second TSV structures 30B. The alignment key AK9 may include a circular region having a diameter of about 10 to about 250 μm, but the scope of the inventive concept is not limited thereto.

At least one of the plurality of second TSV structures 30B configuring the alignment key AK9 may be arranged in line with the ninth pitch P9 together with one of the plurality of first TSV structures 30A.

In FIGS. 2A to 3H, examples in which the plurality of second TSV structures 30B are formed in the second region 120 configuring the alignment keys AK1, AK2, AK3, AK4, AK5, AK6, AK7, AK8, and AK9 are illustrated, but the scope of the inventive concept is not limited thereto. The alignment keys AK1, AK2, AK3, AK4, AK5, AK6, AK7, AK8, and AK9 in the second region 120 may be formed in at least one selected among the TSV unit regions 20A, 20B, 20C, 20D, 20E, 20F, 20G, 20H, and 20I and the peripheral regions 23A, 23B, 23C, 23D, 23E, 23F, 23H, and 23I, only one second TSV structure 30B may be formed in the second region 120, and two second TSV structures 30B may be formed in the second region 120. The number of the second TSV structures 30B formed in the second region 120 is not limited thereto.

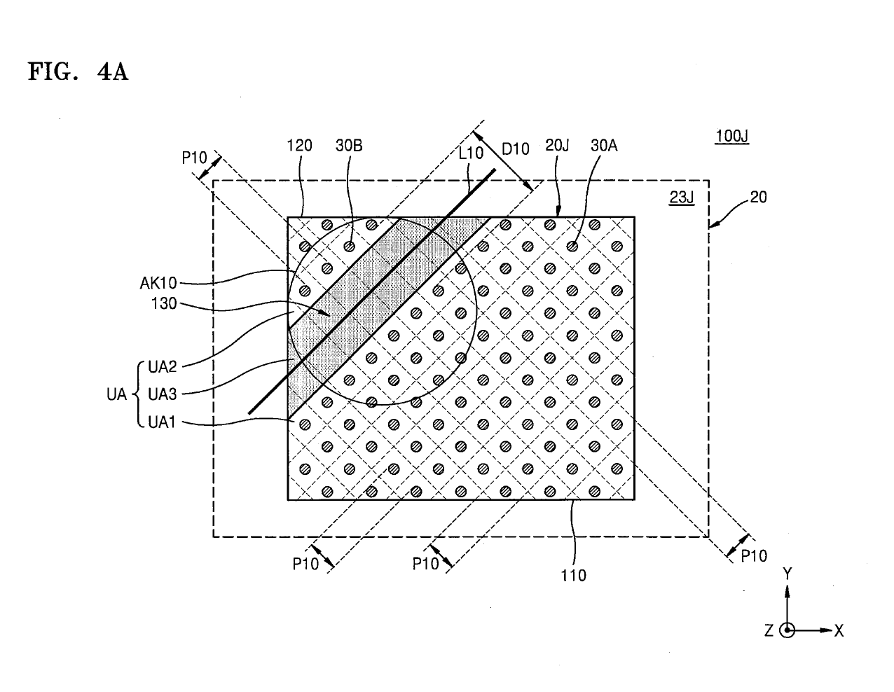

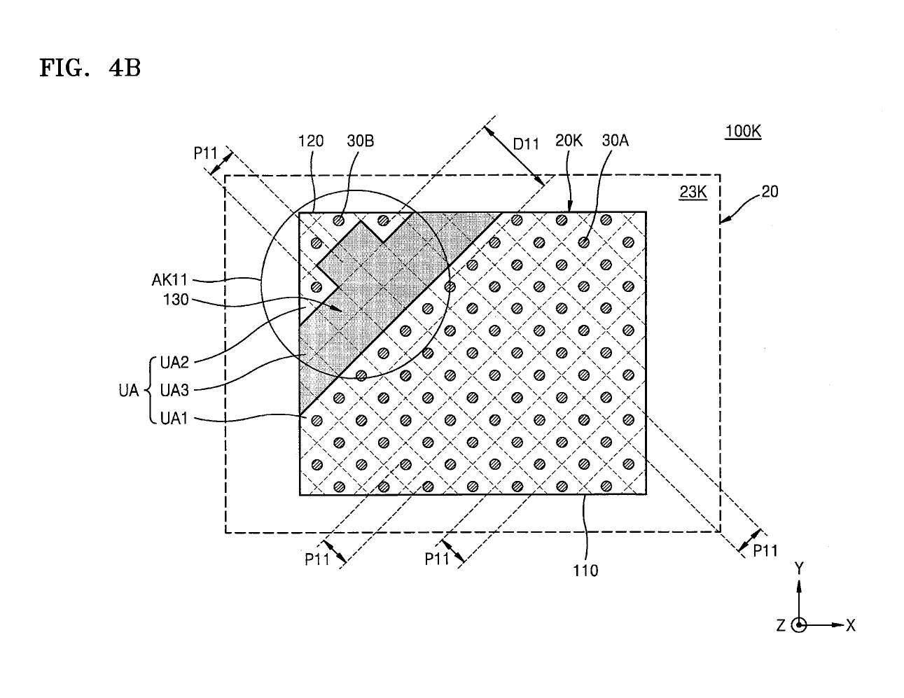

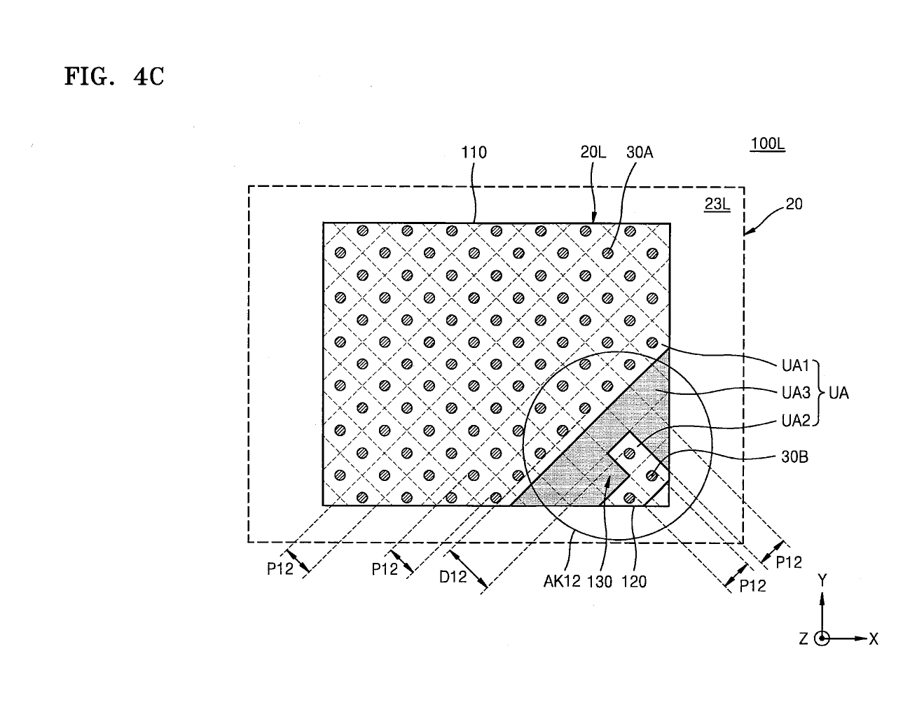

FIGS. 4A to 4C are drawings of integrated circuit devices 100J, 100K, and 100L according to embodiments of the inventive concept and are enlarged plan views of TSV unit regions 20J, 20K, and 20L and their peripheral regions 23J, 23K, and 23L which are applicable as at least one of the plurality of TSV unit regions 22, 24, 26, and 28 included in the TSV region 20 of the integrated circuit device 100 of FIG. 1.

Referring to FIGS. 4A to 4C, examples in which a plurality of unit regions UA having a hexagonal arrangement, and a plurality of first TSV structures 30A formed in a plurality of first unit regions UA1 of the plurality of unit regions UA and a plurality of second TSV structures 30B formed in a plurality of second unit regions UA2 of the plurality of unit regions UA having the illustrated arrangement.

Referring to FIG. 4A, the integrated circuit device 100J may have the same structure as the integrated circuit device 100A shown in FIGS. 2A and 2B except that the plurality of unit regions UA, the plurality of first TSV structures 30A formed in the plurality of first unit regions UA1 of the plurality of unit regions UA and the plurality of second TSV structures 30B formed in the plurality of second unit region UA2 of the plurality of unit region UA have the oblique arrangement, respectively. In other words, the oblique arrangement shown in FIGS. 4A to 4C is provided so that the portions of the unit region UA1 and unit region UA2 face one another so that the spacing between those two unit regions is uniform compared to, for example, the arrangement shown in FIG. 2A where the spacing follows a serpentine pattern.

The TSV region 20 of the integrated circuit device 100J may include the TSV unit region 20J and the peripheral region 23J surrounding the TSV unit region 20J.

The TSV region 20 of the integrated circuit device 100J may include a first region 110 in which the plurality of first TSV structures 30A are arranged with a tenth pitch P10 in the TSV unit region 20J. Further, the TSV region 20 may be included in the TSV unit region 20J and may include a second region 120 including a plurality of second TSV structures 30B. The plurality of second TSV structures 30B may be arranged with the tenth pitch P10 in the second region 120 like the plurality of first TSV structures 30A formed in the first region 110.

The TSV region 20 may further include a third region 130 providing a spacing distance D10 between the first region 110 and the second region 120 greater than the tenth pitch P10 between the first TSV structure 30A and the second TSV structure 30B by being interposed between the first region 110 and the second region 120. The third region 130 may not have a TSV structure.

The integrated circuit device 100J may include an alignment key AK10 configured as a combination at least a portion of the third region 130 and at least one of the plurality of second TSV structures 30B. The alignment key AK10 may have a circular region having a diameter of 10 to about 250 μm, but the scope of the inventive concept is not limited thereto.

The plurality of third unit regions UA3 may be arranged so that the third region 130 extended along an oblique direction represented by “L10” in FIG. 4A is provided.

Referring to FIG. 4B, a TSV region 20 of the integrated circuit device 100K may include the TSV unit region 20K and the peripheral region 23K surrounding the TSV unit region 20K.

In the integrated circuit device 100K, the plurality of first TSV structures 30A formed in the plurality of first unit regions UA1 of the plurality of unit regions UA, and the plurality of second TSV structures 30B formed in the plurality of second unit regions UA2 of the plurality of unit regions UA may be formed to have the oblique arrangement, respectively.

The TSV region 20 of the integrated circuit device 100K may include a first region 110 in which the plurality of first TSV structures 30A are arranged with a eleventh pitch P11 in the TSV unit region 20K, and a second region 120 including the plurality of second TSV structures 30B. The plurality of second TSV structures 30B may be arranged with the eleventh pitch P11 in the second region 120 like the plurality of first TSV structures 30A formed in the first region 110.

The TSV region 20 may further include a third region 130 providing a spacing distance D11 between the first region 110 and the second region 120 greater than the eleventh pitch P11 between the first TSV structure 30A and the second TSV structure by being interposed between the first region 110 and the second region 120. The third region 130 may not include a TSV structure.

The integrated circuit device 100K may include an alignment key AK11 configured as a combination of at least a portion of the third region 130 and at least one of the plurality of second TSV structures 30B. The alignment key AK11 may include a circular region having about 10 to about 250 μm, but the scope of the inventive concept is not limited thereto.

Referring to FIG. 4C, a TSV region 20 of the integrated circuit device 100L may include the TSV unit region 20L and the peripheral region 23L surrounding the TSV unit region 20L.

In the integrated circuit device 100L, the plurality of first TSV structures 30A formed in the plurality of first unit regions UA1 of the plurality of unit regions UA, and the plurality of second TSV structures 30B formed in the plurality of second unit regions UA2 of the plurality of unit regions UA may be formed in an oblique arrangement, respectively.

The TSV region 20 of the integrated circuit device 100L may include a first region 110 in which the plurality of first TSV structures 30A arranged with a twelfth pitch P12 in the TSV unit region 20K, and a second region 30B including the plurality of second TSV structures 30B. The plurality of second TSV structures 30B may be arranged with the twelfth pitch P12 in the second region 120 like the plurality of first TSV structures 30A formed in the first region 110.

The TSV region 20 may further include a third region 130 providing a spacing distance D12 between the first region 110 and the second region 120 greater than the twelfth pitch P12 between the first TSV structure 30A and the second TSV structure 30B by being interposed between the first region 110 and the second region 120. The third region 130 may not include a TSV structure.

The integrated circuit device 100L may include an alignment key AK12 configured as a combination of at least a portion of the third region 130 and at least one of the plurality of second TSV structures 30B. The alignment key AK12 may include a circular region having about 10 to about 250 μm, but the scope of the inventive concept is not limited thereto.

The TSV unit regions 20J, 20K, and 20L shown in FIGS. 4A to 4C may configure at least one of the plurality of unit regions 22, 24, 26, and 28 configuring the TSV region 20 shown in FIG. 1.

In the integrated circuit devices 100J, 100K, and 100L illustrated in FIGS. 4A to 4C, the examples in which each of the alignment keys AK10, AK11, and AK12 have the plurality of second TSV structures 30B are illustrated, but the scope of the inventive concept is not limited thereto. According to the scope of the inventive concept, the second region 120 configuring a portion of the alignment key AK10, AK11, or AK12 may be formed in at least one region selected among the TSV unit regions 20J, 20K, and 20L and the peripheral regions 23J, 23K, and 23L, only one second TSV structure 30B may be formed in the second region 120, and two second TSV structures 30B may be formed in the second region 120. The number of the second TSV structures 30B formed in the second region 120 is not limited thereto.

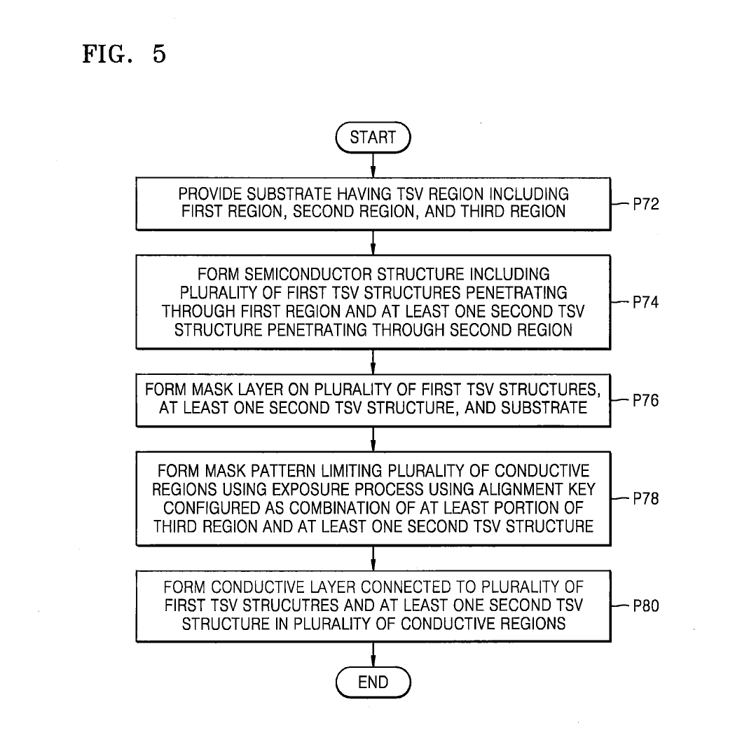

FIG. 5 is a flowchart for describing a method of manufacturing an integrated circuit device according to embodiments of the inventive concept.

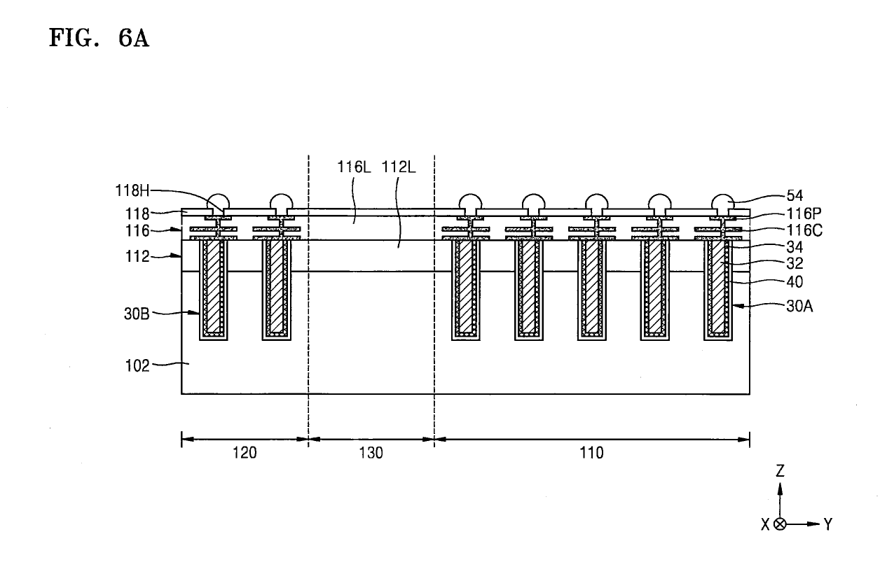

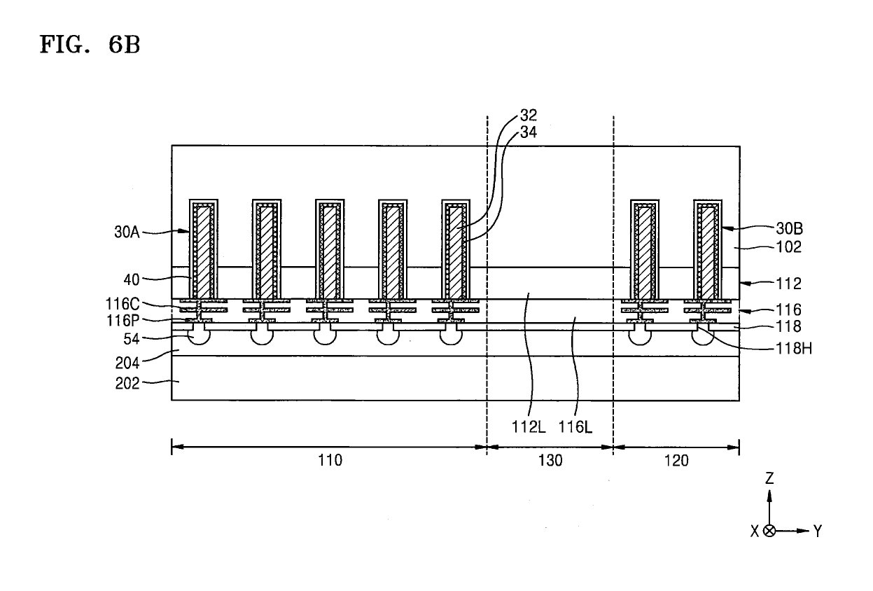

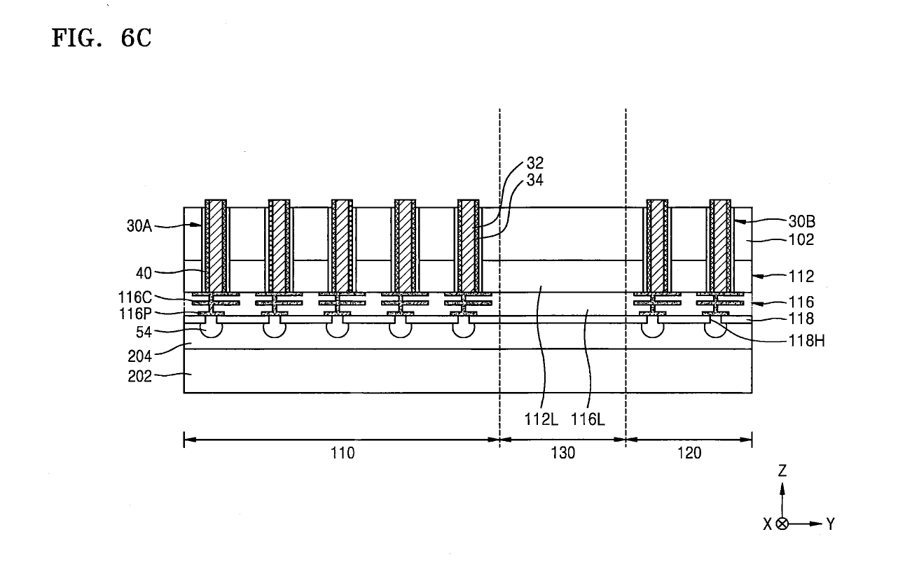

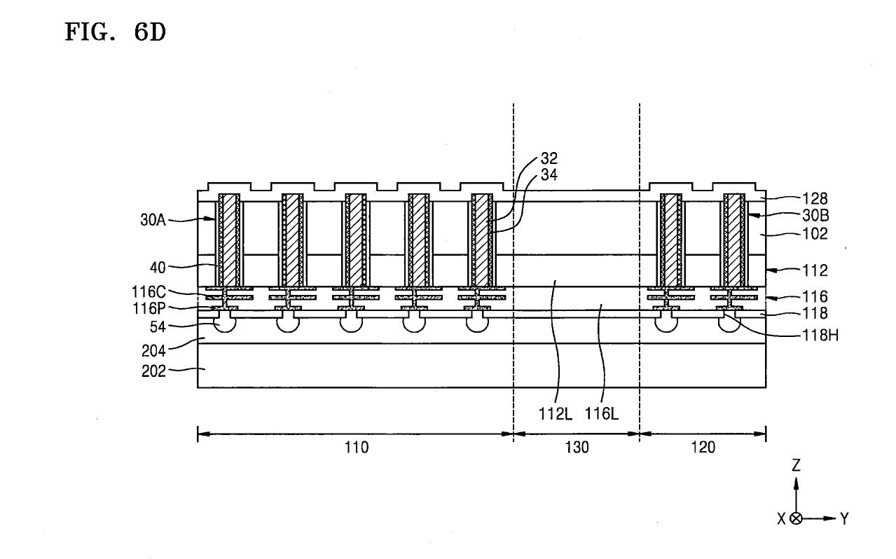

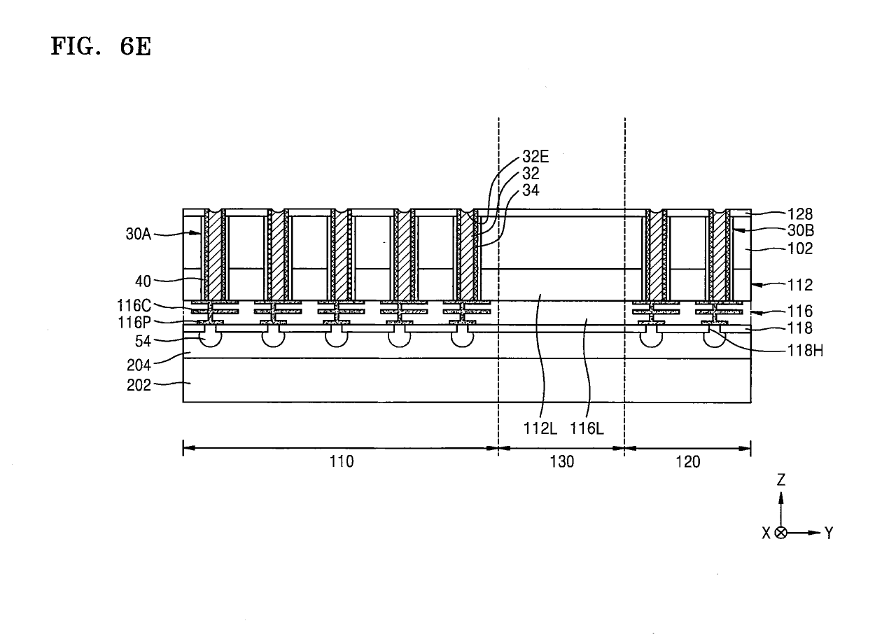

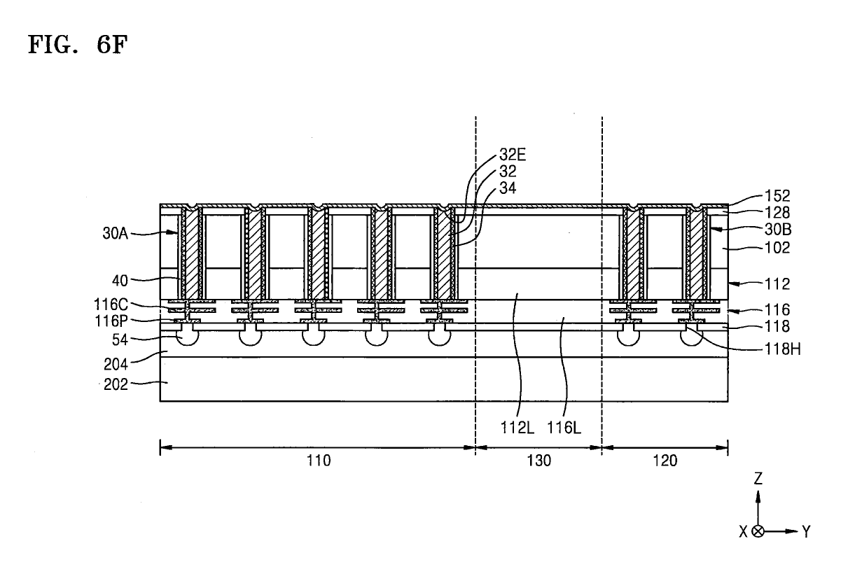

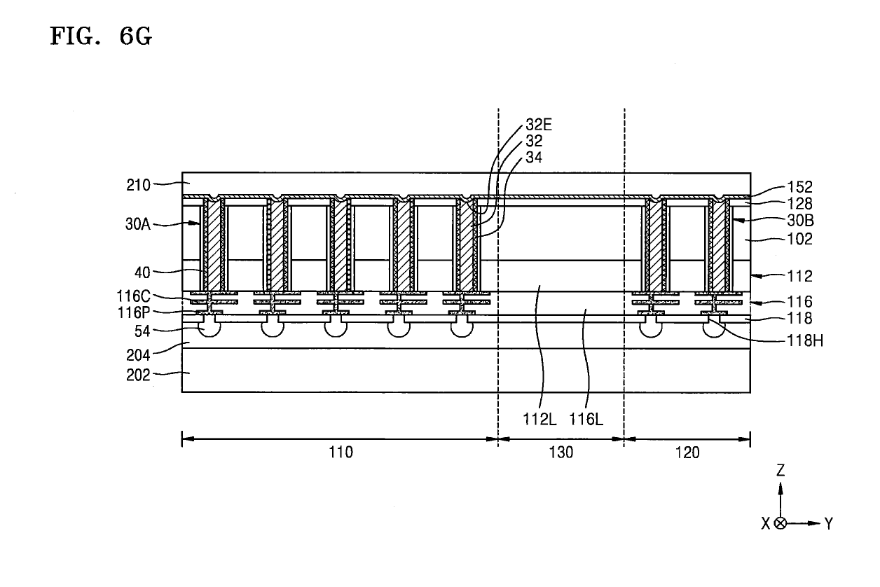

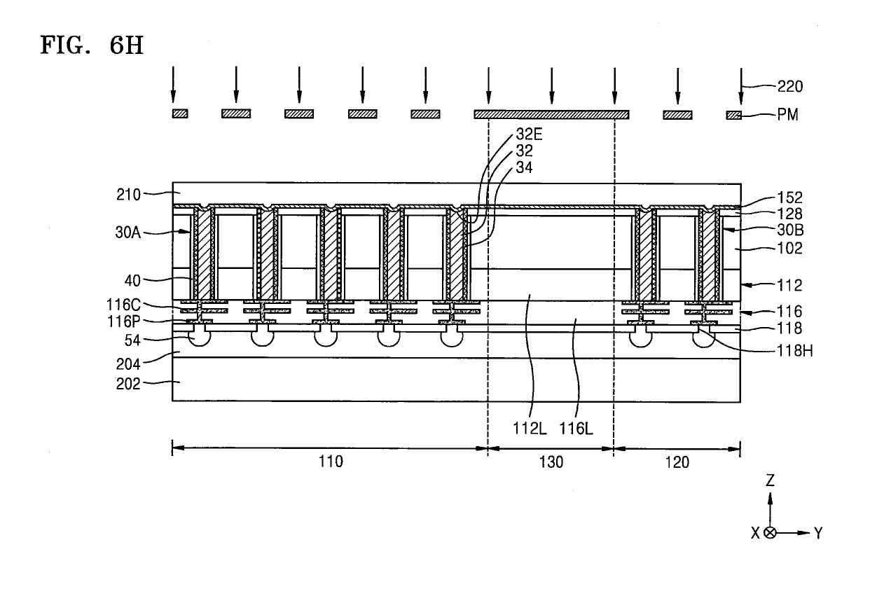

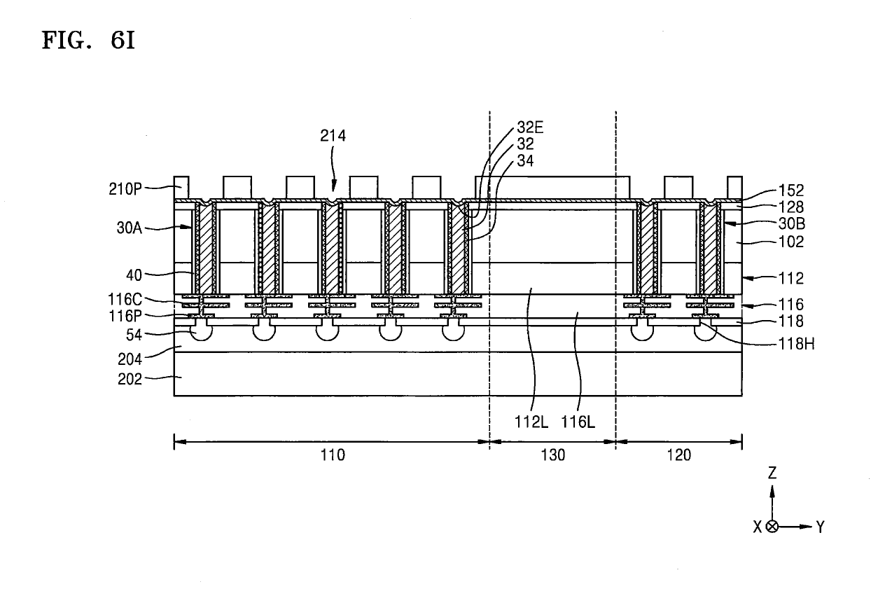

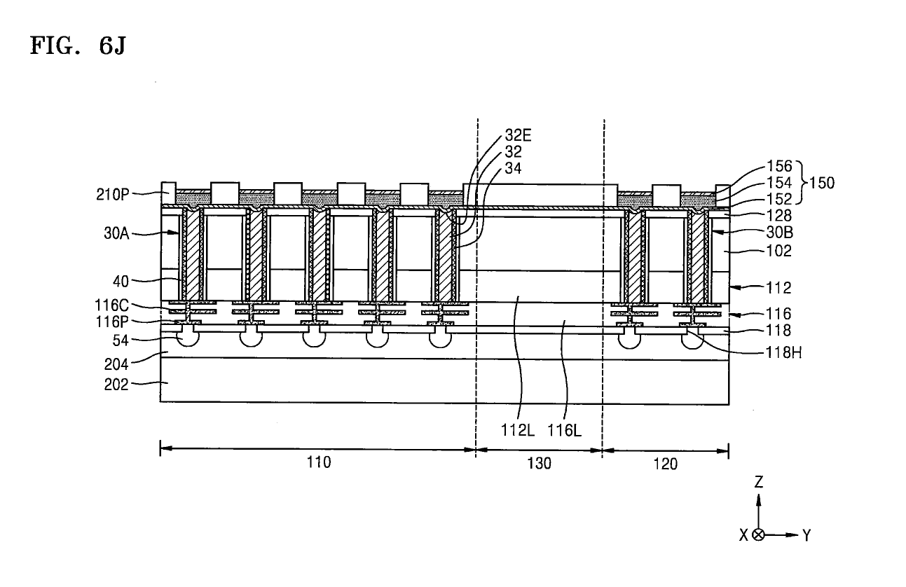

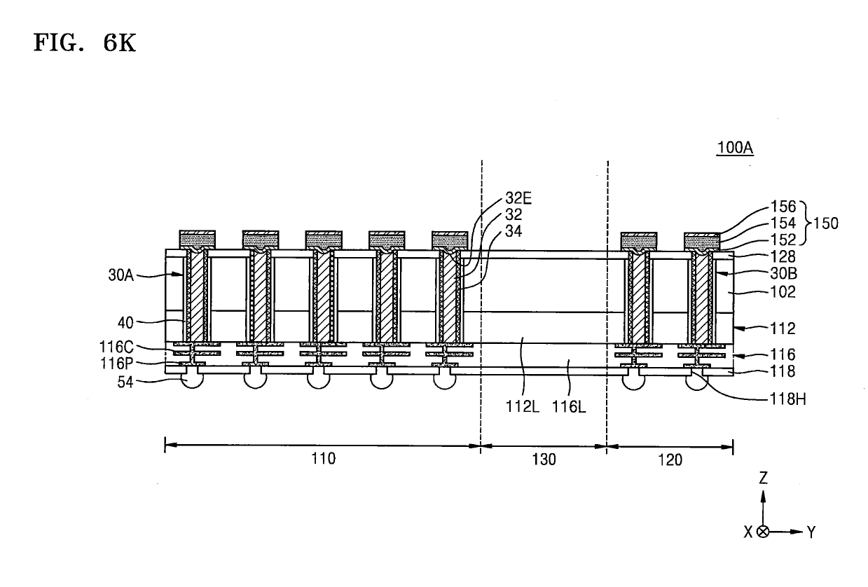

FIGS. 6A to 6K are cross-sectional views illustrating a method of manufacturing an integrated circuit device according to embodiments of the inventive concept.

A method of manufacturing the integrated circuit device 100A shown in FIGS. 2A to 2C will be described with reference to FIGS. 5, and 6A to 6K.

Referring to FIGS. 5 and 6A, a substrate 102 having a TSV region 20 having a first region 110, a second region 120, and a third region 130 may be provided (P72). The third region 130 may be a region interposed between the first region 110 and the second region 120.

A TSV structure may not be included in the third region 130 of the TSV region 20, and a semiconductor structure including a plurality of first TSV structures 30A penetrating through the first region 110, and at least one second TSV structure 30B penetrating through the second region 120 may be formed (P74).

In some embodiments, processes described in FIGS. 6A to 6F may be performed in order to form the semiconductor structure including the plurality of first TSV structures 30A penetrating through the first region 110, and the at least one second TSV structure 30B penetrating through the second region 120.

In some embodiments, the semiconductor structure may include the substrate 102, a FEOL structure 112, and a BEOL structure 116 shown in FIG. 6A. The plurality of first TSV structures 30A and at least one second TSV structure 30B may be formed to penetrate through the substrate 102 and the FEOL structure 112 in the TSV region 20 by the via-middle process.

After forming a FEOL structure 112 on the substrate 102, the plurality of first TSV structures 30A and a plurality of second TSV structure 30B extended to the inside of the substrate 102 by penetrating through the FEOL structure 112 in the first region 110 and the second region 120 included in a TSV unit region 20A of the TSV region 20 may be formed. Each of the plurality of first TSV structures 30A and the plurality of second TSV structures 30B may be formed so that a sidewall of each of the plurality of first TSV structures 30A and the plurality of second TSV structures 30B is spaced apart from the substrate 102 and the FEOL structure 112 by being surrounded by a via insulating film 40.

In some embodiments, each of the plurality of first TSV structures 30A and the plurality of second TSV structures 30B may be formed to have a diameter of about 6 to about 7 μm. In the first region 110 and the second region 120, the plurality of first TSV structures 30A and the plurality of second TSV structures 30B may be formed to maintain a constant interval of a first pitch P1 which is equal to or less than about 150 μm. The plurality of first TSV structures 30A and the plurality of second TSV structures 30B may be formed to have the layout shown in FIG. 2A.

In some other embodiments, the plurality of first TSV structures 30A and the plurality of second TSV structures 30B may be formed to have various layouts in order to form the integrated circuit devices 100A to 100L shown in FIGS. 3A to 4C, or integrated circuit devices according to modifications thereof and modified embodiments.

After forming the FEOL structure 112, and the BEOL structure 116 including a multilayer interconnection structure 116C, a plurality of bonding pads 116P, and a metal interlayer insulating film 116L for insulating the multilayer interconnection structure 116C and the plurality of bonding pads 116P from other peripheral conductive regions on the plurality of first TSV structures 30A and the plurality of second TSV structures 30B, a passivation layer 118 may be formed on the BEOL structure 116. After forming a plurality of holes 118H to expose the plurality of bonding pads 116P on the passivation layer 118, a plurality of first connection terminals 54 connected to the plurality of bonding pads 116P through the plurality of holes 118H on the passivation layer 118 may be formed.

Referring to FIG. 6B, a carrier substrate 202 covering the plurality of bonding pads 116P may be attached on a front side of the substrate 102.

A bonding layer 204 may be interposed between the plurality of bonding pads 116P and the carrier substrate 202 in order to attach the carrier substrate 202.

The carrier substrate 202 may support the substrate 102 when performing a grinding process on a back side of the substrate 102 or handling the substrate 102. The carrier substrate 202 may be formed as a quartz substrate, a glass substrate, a semiconductor substrate, a ceramic substrate, or a metal substrate, etc., but is not limited thereto.

The bonding layer 204 may be formed using a non-conductive film (NCF), an anisotropic conductive film (ACF), an ultra violet (UV) film, an instant adhesive, a thermosetting adhesive, a laser hardening adhesive, an ultrasonic wave hardening adhesive, a non-conductive paste (NCP), etc., but is not limited thereto.

Referring to FIG. 6C, ends of the plurality of first TSV structures 30A and the plurality of second TSV structures 30B may be exposed to the back side of the substrate 102 by grinding the back side of the substrate 102. In this case, a portion of the substrate 102, and a portion of the via insulating film 40 may be removed so that a portion of the sidewall of the end of each of the plurality of first TSV structures 30A and the plurality of second TSV structures 30B is exposed.

After grinding the back side of the substrate 102, a thickness of the remaining substrate 102 may be equal to or less than about 50 μm.

Referring to FIG. 6D, a back side passivation layer 128 covering the back side of the substrate 102 and the exposed end of each of the plurality of first TSV structures 30A and the plurality of second TSV structures 30B may be formed.

The back side passivation layer 128 may be formed of a silicon oxide, a silicon nitride, polymer, or a combination thereof. For example, the back side passivation layer 128 may have a double layer structure of the silicon oxide and the silicon nitride. In some embodiments, a chemical vapor deposition (CVD) process may be used to form the back side passivation layer 128.

Referring to FIG. 6E, the back side passivation layer 128 may be ground until the end of each of the plurality of first TSV structures 30A and the plurality of second TSV structures 30B are exposed in the back side of the substrate 102.

While the back side passivation layer 128 is ground, a portion of a surface of the end of each of the plurality of first TSV structures 30A and the plurality of second TSV structures 30B exposed in the back side of the substrate 102 may be removed to lead a dishing phenomenon due to a difference of a grinding speed between an insulating material configuring the back side passivation layer 128 and conductive materials configuring the plurality of first TSV structures 30A and the plurality of second TSV structures 30B. As a result, a recessed end surface 32E may be obtained as a level of a center portion is lower than a level of an edge side in the surface of the end of each of the plurality of first TSV structures 30A and the plurality of second TSV structures 30B.

Referring to FIG. 6F, a UBM layer 152 which conformally covers the exposed surface of the ground back side passivation layer 128 and the recessed end surface 32E of each of the plurality of first TSV structures 30A and the plurality of second TSV structures 30B may be formed.

In some embodiments, the UBM layer 152 may include films having various compositions according to a configuration material of a second connection terminal 150. In some embodiments, the UBM layer 152 may be formed of titanium (Ti), copper (Cu), nickel (Ni), gold (Au), nickel vanadium (NiV), nickel phosphide (NiP), titanium nickel (TiNi), titanium tungsten (TiW), tantalum nitrogen (TaN), aluminum (Al), palladium (Pd), copper chromium (CuCr), or a combination thereof. For example, the UBM layer 152 may have a Ti/Cu laminated structure, a Ti/Ni laminated structure, a Ti/NiP laminated structure, a Ni/Cu laminated structure, a NiV/Cu laminated structure, a Cr/Cu/Au laminated structure, a Cr/CrCu/Cu laminated structure, a TiWCu compound, a TiWCu/Cu laminated structure, a TiWNiV compound, an Al/Ni/Au laminated structure, an Al/NiP/Au laminated structure, a laminated structure of a Ti/TiNi/CuNi compound, a Ti/Ni/Pd laminated structure, a Ni/Pd/Au laminated structure, or a NiP/Pd/Au laminated structure. For example, the UBM layer 152 may have a double layer structure formed of a Ti film having a thickness of about 1000 to about 2000 Å and a Cu film having a thickness of about 500 to about 1500 Å.

Referring to FIG. 6G, a mask layer 210 may be formed on the plurality of first TSV structures 30A, at least one second TSV structure 30B, and the substrate 102 (P76).

The mask layer 210 may be formed on the back side of the substrate 102 overall to cover the UBM layer 152 on the plurality of first TSV structures 30A and the plurality of second TSV structures 30B.

The mask layer 210 may be a photoresist pattern.

As shown in FIGS. 6H and 6J, a mask pattern 210P (refer to FIG. 6I) limiting a plurality of conductive regions 214 may be formed by patterning the mask layer 210 using an exposure process using the alignment key AK1 (refer to FIG. 2A) configured as a combination of at least a portion of the third region 130 and at least one second TSV structure 30B (P78).

In more detail, as shown in FIG. 6H, a portion of the mask layer 210 may be formed by irradiating light 220 onto the mask layer 210 through a photo mask PM using the alignment key AK1 (refer to, for example FIG. 2A) configured as a combination of a portion of the plurality of second TSV structures 30B formed in the second region 120 and a portion of the third region 130 which does not include a TSV structure.

In the exposure process of the mask layer 210, another alignment key excluding the alignment key AK1 formed on the substrate 102 may not be used. Accordingly, it may not be necessary to form an alignment key different from the alignment key AK1 on the substrate 102 in order to perform the exposure process of the mask layer 210. Accordingly, it may not be necessary to perform a separate process for forming the alignment key in a portion of the substrate 102, for example, a scribe lane region, etc., and a manufacturing process of an integrated circuit device including a TSV structure may be simplified and productivity may be improved.

An example of performing the exposure process using the alignment key AK1 shown in FIG. 2A is illustrated, but when forming the integrated circuit devices 100B to 100L shown in FIGS. 3A to 4C, the exposure process may be performed using the alignment keys AK2 to AK12 included in the integrated circuit devices 100B to 100L.

Referring to FIG. 6I, the mask pattern 210P limiting the plurality of conductive regions 214 exposing portions covering the plurality of first TSV structures 30A and the plurality of second TSV structures 30B of the UBM layer 152 may be formed by developing the exposed mask layer 210.

A conductive layer may be formed in the plurality of conductive regions 214 (P80) conductive layer may be connected to the plurality of first TSV structures 30A and at least one second TSV structure 30B.

In order to perform the operation shown in P80 of FIG. 5, processes are described with reference to FIGS. 6J to 6K.

For example, in order to form the conductive layer (P80), a plurality of first metal pad layers 154 and a plurality of second metal pad layers 156 may be formed on portions covering the plurality of first TSV structures 30A and the plurality of second TSV structures 30B in the UBM layer 152 as shown in FIG. 6J.

The plurality of first metal pad layers 154 and the plurality of second metal pad layers 156 may be connected to the plurality of first TSV structures 30A and the plurality of second TSV structures 30B through the UBM layer 152.

In more detail, in order to form a conductive layer in the plurality of conductive regions 214, the first metal pad layer 154 and the second metal pad layer 156 may be sequentially formed on an upper surface of the UBM layer 152 exposed in the plurality of conductive regions 214 through the mask pattern 210P. The plurality of first metal pad layers 154 and the plurality of second metal pad layers 156 may configure a plurality of second connection terminals 150 together with a portion of the UBM layer 152.

The first metal pad layer 154 and the second metal pad layer 156 may be formed using an electroplating process.

In some embodiments, each of the first metal pad layer 154 and the second metal pad layer 156 may be formed of Ni, Au, Cu, Al, or a combination thereof. For example, the first metal pad layer 154 may be formed as a Ni film having a thickness of about 3 to about 8 μm, and the second metal pad layer 156 may be formed as an Au film having a thickness of about 0.1 to about 0.3 μm, but the configuration materials of the first metal pad layer 154 and the second metal pad layer 156 are not limited thereto.

An example in which each of the plurality of second connection terminals 150 has a triple layer structure including the UBM layer 152, the first metal pad layer 154, and the second metal pad layer 156 is illustrated, but the scope of the inventive concept is not limited thereto. The second connection terminal 150 may be formed as a metal film having various materials, and the number of layers of the metal film may be varied within the scope of the inventive concept.

Referring to FIG. 6K, the plurality of second connection terminals 150 may remain in the back side of the substrate 102 by removing the mask pattern 210P and portions of the UBM layer 152 under the mask pattern 210P from a resultant product in which the plurality of second connection terminals 150 are formed.

Further, the plurality of first connection terminals 54 may be exposed by removing the carrier substrate 202 and the bonding layer 204 covering the front side of the substrate 102.

According to the method of manufacturing an integrated circuit device according to embodiments of the inventive concept described with reference to FIGS. 5, and 6A to 6K, in the exposure process of the mask layer 210, the exposure process may be performed using the alignment key AK1 configured as a combination of at least one second TSV structure 30B and at least a portion of the third region 130. Accordingly, it may not be necessary to form another alignment key in addition to the alignment key AK1 for the exposure process of the mask layer 210. Accordingly, it may not be necessary to perform a separate process for forming an alignment key in a portion of the substrate 102, for example, a scribe lane region, etc. Accordingly, the manufacturing process of an integrated circuit device including a TSV structure may be simplified and the productivity may be improved.

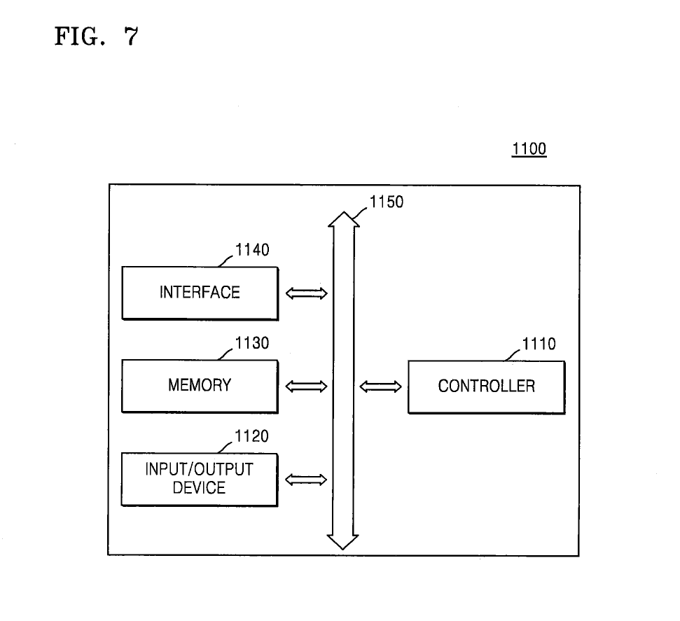

FIG. 7 is a block diagram illustrating a configuration of an important portion of an electronic device according to embodiments of the inventive concept.

An electronic device 1100 may include a controller 1110, an input/output device 1120, a memory 1130, and an interface 1140. The electronic device 1100 may be a mobile system, or a system transceiving information. In some embodiments, the mobile system may be at least one among a personal digital assistant (PDA), a portable computer, a web tablet, a wireless phone, a mobile phone, a digital music player, or a memory card.

In some embodiments, the controller 1110 may be a microprocessor, a digital signal processor, or a micro-controller.

The input/output device 1120 may be used for data input/output of the electronic device 1100. The electronic device 1100 may be connected to an external device, for example, a personal computer or a network, using the input/output device 1120, and exchange data with the external device. In some embodiments, the input/output device 1120 may be a keypad, a keyboard, or a display.

In some embodiments, the memory 1130 may store a code and/or data for an operation of the controller 1110. In some other embodiments, the memory 1130 may store data processed by the controller 1110. At least one of the controller 1110 and the memory 1130 may include at least one among the integrated circuit devices 100, 100A, 100B, 100C, 100D, 100E, 100F, 100G, 100H, 100I, 100J, 100K, and 100L described with reference to FIGS. 1 to 4C.

The interface 1140 may perform the role of a data transmission path between the electronic device 1100 and another external device. The controller 1110, the input/output device 1120, the memory 1130, and the interface 1140 may communicate with each other through a bus 1150.

The electronic device 1100 may be included in a mobile phone, an MP3 player, a navigation system, a portable multimedia player (PMP), a solid state disk (SSD), or household appliances.

In some embodiments, an integrated may include an alignment key including a combination of at least one TSV structure and a region which does not include the TSV structure which is a region adjacent to the at least one TSV structure. The at least one TSV structure used in the alignment key may be an active TSV structure which electrically connects devices, on a substrate, to conductive components on a back side of the substrate, which perform electrical functions in the integrated circuit device.

As appreciated by the present inventors, since functional components (e.g., TSV structures) are used as the alignment key, it may not be necessary to perform a separate process to form an dedicated alignment key in another region of the substrate, for example, the scribe lane region, etc. Accordingly, the manufacturing process of an integrated circuit device including a TSV device may be simplified and the productivity may be improved.

While the inventive concept has been particularly shown and described with reference to embodiments thereof, it should be understood that various changes in form and details may be made therein without departing from the spirit and scope of the following claims.

1. An integrated circuit device, comprising:
a through silicon via (TSV) unit region including a first region having a plurality of first TSV structures penetrating through a substrate, the plurality of first TSV structures arranged in the TSV unit region at a constant first pitch in a row direction and in a column direction;
a peripheral region surrounding the TSV unit region to separate the TSV unit region from adjacent decoder circuits;
a second region included in at least one region among the TSV unit region and the peripheral region, the second region including at least one second TSV structure;
a third region free of TSV structures, the third region configured to provide a spacing distance between the first region and the second region that is greater than the first pitch; and
an alignment key configured as a combination of at least a portion of the third region and the at least one second TSV structure.

2. The integrated circuit device of claim 1, wherein the TSV unit region includes a plurality of unit regions arranged with the first pitch along the row direction and the column direction, and
the first region includes a plurality of first unit regions among the plurality of unit regions, and respective ones of the plurality of first TSV structures are located in respective ones of the plurality of first unit regions.

3. The integrated circuit device of claim 2, wherein the second region includes at least one second unit region among the plurality of unit regions in the TSV unit region, and
a respective one of the at least one second TSV structure is located in a respective one of the at least one second unit region.

4. The integrated circuit device of claim 3, wherein the third region includes at least one third unit region among the plurality of unit regions, and
the first region and the second region are located on opposite sides of the third unit region.

5. The integrated circuit device of claim 3, wherein the third region includes a plurality of third unit regions among the plurality of unit regions,
the plurality of third unit regions are arranged to provide the third region extended between the first region and the second region along at least one of the row direction, the column direction, and an oblique direction intersecting the row direction and the column direction.

6. The integrated circuit device of claim 2, wherein the second region is included in the TSV unit region.

7. The integrated circuit device of claim 2, wherein the second region and the third region are included in the peripheral region, and
the at least one second TSV structure is arranged in line with the first pitch together with a portion of the plurality of first TSV structures.

8. The integrated circuit device of claim 2, wherein a plurality of second TSV structures are in the second region, and
the alignment key includes at least one of the plurality of second TSV structures.

9.-13. (canceled)

14. An integrated circuit device, comprising:
a plurality of through-silicon via (TSV) unit regions including a plurality of first TSV structures penetrating through a substrate and regularly arranged with a first pitch;
a peripheral region surrounding the plurality of TSV unit regions to separate the TSV unit regions from adjacent decoder circuits;
at least one second TSV structure located across a spacing region, which provides a spacing distance greater than the first pitch, spaced apart from the plurality of first TSV structures, the at least one second TSV structure located in the plurality of TSV unit regions and the peripheral region; and
an alignment key comprising a combination of the at least one second TSV structure and the spacing region.

15. The integrated circuit device of claim 14, wherein the at least one second TSV structure has the same structure as one of the first TSV structures, and
a TSV structure is not formed in the spacing region.

16. An integrated circuit device, comprising:
a first Through Via (TV) region including first TV structures spaced apart from one another at a first pitch in first and second directions;
a second TV region including second TV structures spaced apart from one another at the first pitch in the first and second directions;
a TV free region separating directly adjacent first and second TV structures from one another by a spacing distance measured in the first or second direction that is greater than the first pitch; and
an alignment key defined as a geometric pattern including one of the second TV structures and the TV free region.

17. The device of claim 16 wherein the first and second TV structures penetrate through a substrate on which the device is located.

18. The device of claim 17 wherein the first and second TV structures comprise respective first and second electrically active TV structures coupled to integrated circuit structures on the substrate.

19. The device of claim 16 wherein the second TV region lies within outermost portions of the first TV region in the first and second directions.

20. The device of claim 19 further comprising:
a peripheral region, free of TV structures, surrounding the first and second TV regions to separate the first and second TV regions from adjacent decoder circuits.

21. The device of claim 16 wherein the second TV region lies outside outermost portions of the first TV region in the first and second directions within a peripheral region, free of TV structures, surrounding the first and second TV regions to separate the first and second TV regions from adjacent decoder circuits.

22. The device of claim 16 wherein the TV free region has a perimeter with the first TV region that extends in the first and second directions.

23. The device of claim 22 wherein the first and second directions are oblique relative to row and column directions of a memory cell array in the device.

24. The device of claim 16 wherein a diameter of the alignment key is about 10 um to about 250 um.

25. The device of claim 16 wherein the second TV structures extend in the first and second directions to define a portion of the geometric pattern of the alignment key.
